(19) United States
(12) Patent Application Publication
(10) Pub. No.: US 2014/0140018 A1
(43) Pub. Date: May 22, 2014

(54) Flexible Printed Circuit Connector Protection Structures

(71) Applicant: APPLE INC., Cupertino, CA (US)

(72) Inventors: Shayan Malek, San Jose, CA (US); Michael B. Wittenberg, Sunnyvale, CA (US); Warren Z. Jones, San Jose, CA (US)

(73) Assignee: Apple Inc., Cupertino, CA (US)

(21) Appl. No.: 13/682,402

(22) Filed: Nov. 20, 2012

(51) Int. Cl. H05K 1/14; H05K 7/14

(52) U.S. Cl. CPC H05K 1/147; H05K 1/14; H05K 7/14
USPC 361/749; 361/784; 361/752

(57) ABSTRACT

Protection structures may be provided to protect connectors, printed circuits, and other internal device components from damage. Components may shift within a device if the device is unexpectedly dropped. Protection structures can shield printed circuit connectors and other structures so that component movement during a drop event does not dislodge a printed circuit connector or otherwise damage a device. A cowling can be used to hold a board-to-board connector or other connector together. The cowling may have a protruding portion that is bent to form a protective wall. Plastic structures may be molded onto the cowling to form protective walls. Protection structures for printed circuit connectors and other internal device components may be formed from spring-based structures that clip onto the edge of a printed circuit board.

### BACKGROUND

This relates generally to electronic devices and, more particularly, to electronic devices with internal components such as printed circuits and printed circuit connectors.

Electronic devices often include printed circuits. Rigid printed circuit boards are formed from stiff substrates such as fiberglass-filled epoxy. Flexible printed circuits are formed from flexible polymer layers such as sheets of polyimide.

Electrical components can be mounted on printed circuits. For example, integrated circuits, sensors, and other devices can be soldered to a printed circuit. Patterned metal traces on the printed circuits are used to interconnect these devices. In some devices, signals are routed over cables that are formed from patterned metal traces a flexible printed circuit.

During unintended impact events such as situations in which an electronic device is dropped on a hard surface, internal components can come into contact with structures such as printed circuits in the interior of the electronic device. If care is not taken, this can lead to damage to the structures. For example, printed circuits and other structures can become damaged and printed circuit connectors can become dislodged.

It would therefore be desirable to be able to provide improved arrangements for mounting and protecting printed circuits and other components in an electronic device.

### SUMMARY

Protection structures may be provided to protect connectors, printed circuits, and other internal device components in an electronic device from damage that might otherwise occur during a drop event. The protection structures can shield a printed circuit connector and other structures so that component movement during a drop event does not dislodge the printed circuit connector or otherwise damage a device.

Electronic devices may include flexible and rigid printed circuits and other substrates that are interconnected using connectors such as board-to-board connectors. A board-to-board connector may, for example, be used to couple a flexible printed circuit to a rigid printed circuit. In this type of configuration a metal bracket structure may be used to form a cowling on the printed circuit. The cowling can be used to hold the board-to-board connector or other connector together on the printed circuit.

The cowling may be formed from a metal structure that has a protruding tab portion. The tip of the protruding tab portion may be bent to form a protective wall is perpendicular to the rest of the cowling. Plastic structures may also be molded onto a cowling to form protective walls. If desired, protection structures for printed circuit connectors and other internal device components may be formed from spring-based structures that clip onto the edge of a printed circuit board. A flexible printed circuit may pass through an opening that is formed between the spring-based protection structure and the edge of the printed circuit board to which the spring-based protection structure is attached.

Further features, their nature and various advantages will be more apparent from the accompanying drawings and the following detailed description of the preferred embodiments.

### BRIEF DESCRIPTION OF THE DRAWINGS

FIG. 1 is a perspective view of an illustrative electronic device of the type that may be provided with structures for protecting flexible printed circuit connectors and other components in accordance with an embodiment.

FIG. 2 is a schematic view of an illustrative electronic device of the type that may be provided with structures to prevent damage to printed circuits and connectors and other electronic device components during an impact event in accordance with an embodiment.

FIG. 3 is a cross-sectional side view of a portion of an electronic device of the type that may be provided with structures for protecting flexible printed circuit connectors and other components in accordance with an embodiment.

FIG. 4 is a cross-sectional side view of a pair of printed circuits that are being coupled using mating connectors in accordance with an embodiment.

FIG. 5 is a perspective view of a flexible printed circuit that is coupled to a printed circuit board using a board-to-board connector secured using a cowling and protected using a protection structure in accordance with an embodiment.

FIG. 6 is a cross-sectional side view of a portion of an electronic device having a flexible printed circuit connector protection structure configured to protect a connector that is coupling pair of printed circuits in an electronic device in accordance with an embodiment.

FIG. 7 is a perspective view a flexible printed circuit connector protection structure for protecting a flexible printed circuit connection to a printed circuit in accordance with an embodiment.

FIG. 8 is a diagram of a system being used to form flexible printed circuit connector protection structures in accordance with an embodiment.

FIG. 9 is perspective view of a flexible printed circuit connector protection structure that has a vertical wall structure that is being used to prevent contact between a component such as a battery and a flexible printed circuit connector in accordance with an embodiment.

FIG. 10 is perspective view of a flexible printed circuit connector protection structure that has a C-shaped vertical wall structure with a front wall portion and two opposing sidewall portions of opposing edges of a flexible printed circuit to prevent inadvertent contact between a component such as a battery and a flexible printed circuit connector in accordance with an embodiment.

FIG. 11 is an exploded perspective view of a portion of an electronic device having printed circuit boards that are coupled using a connector and having flexible printed circuit connector protection structures to prevent inadvertent contact between a component and the flexible printed circuit connector in accordance with an embodiment.

FIG. 12 is a perspective view of a flexible printed circuit connector protection structure that has been clipped onto the edge of a printed circuit so as to create an opening for a flexible printed circuit between the protection structure and the edge of the printed circuit in accordance with an embodiment.

FIG. 13 is a cross-sectional side view of a flexible printed circuit connector protection structure having spring structures that are attached to a metal support structure using fasteners or welds in accordance with an embodiment.

FIG. 14 is a diagram of a system being used to form flexible printed circuit connector protection structures from spring structures in accordance with an embodiment.

FIG. 15 is perspective view of a flexible printed circuit connector protection structure formed from spring structures that grip a substrate such as a printed circuit so that the protection structure may be clipped to the edge of the printed circuit in accordance with an embodiment.

FIG. 16 is a perspective view of the flexible printed circuit connector protection structures of FIG. 15 being used to protect a connector that forms an electrical connection between a flexible printed circuit and a printed circuit board in accordance with an embodiment.

### DETAILED DESCRIPTION

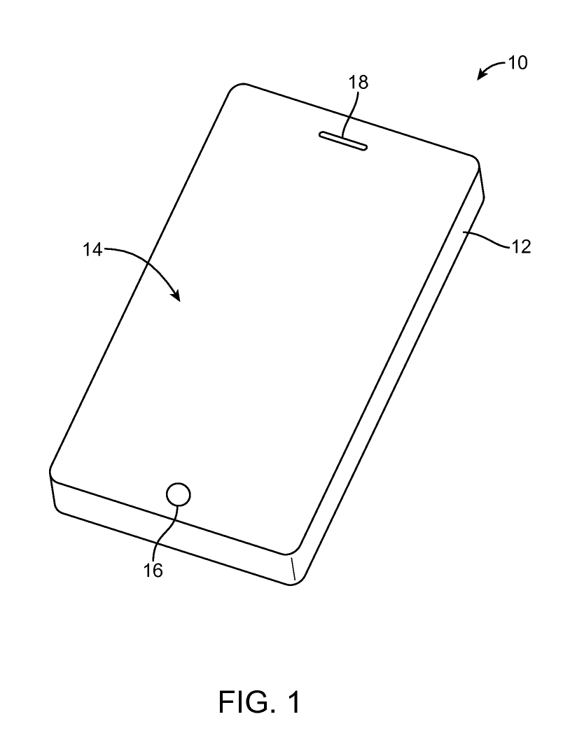

An illustrative electronic device that may be provided with structures for protecting connectors, flexible printed circuits, and other internal components is shown in FIG. 1. Electronic devices such as device 10 of FIG. 1 may be cellular telephones, media players, other handheld portable devices, somewhat smaller portable devices such as wrist-watch devices, pendant devices, or other wearable or miniature devices, gaming equipment, tablet computers, notebook computers, desktop computers, televisions, computer monitors, computers integrated into computer displays, or other electronic equipment.

In the example of FIG. 1, device 10 includes a display such as display 14. Display 14 has been mounted in a housing such as housing 12. Housing 12, which may sometimes be referred to as an enclosure or case, may be formed of plastic, glass, ceramics, fiber composites, metal (e.g., stainless steel, aluminum, etc.), other suitable materials, or a combination of any two or more of these materials. Housing 12 may be formed using a unibody configuration in which some or all of housing 12 is machined or molded as a single structure or may be formed using multiple structures (e.g., an internal frame structure, one or more structures that form exterior housing surfaces, etc.).

Display 14 may be a touch screen display that incorporates a layer of conductive capacitive touch sensor electrodes or other touch sensor components (e.g., resistive touch sensor components, acoustic touch sensor components, force-based touch sensor components, light-based touch sensor components, etc.) or may be a display that is not touch-sensitive. Capacitive touch screen electrodes may be formed from an array of indium tin oxide pads or other transparent conductive structures.

Display 14 may include an array of display pixels formed from liquid crystal display (LCD) components, an array of electrophoretic display pixels, an array of plasma display pixels, an array of organic light-emitting diode display pixels, an array of electrowetting display pixels, or display pixels based on other display technologies. Display 14 may be protected using a display cover layer such as a layer of transparent glass or clear plastic. Openings may be formed in the display cover layer. For example, an opening may be formed in the display cover layer to accommodate a button such as button 16. An opening may also be formed in the display cover layer to accommodate ports such as speaker port 18.

In the center of display 14, display 14 may contain an array of active display pixels. This region is sometimes referred to as the active area of the display. A rectangular ring-shaped region surrounding the periphery of the active display region may not contain any active display pixels and may therefore sometimes be referred to as the inactive area of the display. The display cover layer or other display layers in display 14 may be provided with an opaque masking layer in the inactive region to hide internal components from view by a user. If desired, display 14 may be configured to minimize the size of the inactive border region (e.g., to provide device 10 with a borderless or nearly borderless display arrangement).

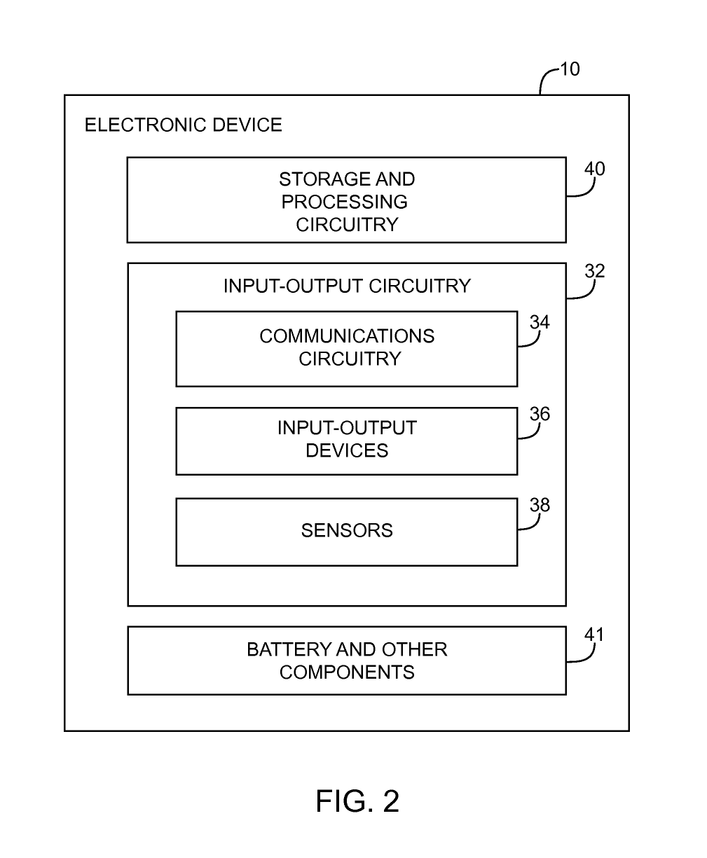

A schematic diagram of device 10 is shown in FIG. 2. As shown in FIG. 2, electronic device 10 may include control circuitry such as storage and processing circuitry 40. Storage and processing circuitry 40 may include one or more different types of storage such as hard disk drive storage, nonvolatile memory (e.g., flash memory or other electrically-programmable-read-only memory), volatile memory (e.g., static or dynamic random-access-memory), etc. Processing circuitry in storage and processing circuitry 40 may be used in controlling the operation of device 10. The processing circuitry may be based on a processor such as a microprocessor and other suitable integrated circuits. With one suitable arrangement, storage and processing circuitry 40 may be used to run software on device 10 such as internet browsing applications, email applications, media playback applications, operating system functions, software for capturing and processing images, software implementing functions associated with gathering and processing sensor data, software that makes adjustments to display brightness and touch sensor functionality, etc.

Input-output circuitry 32 may be used to allow input to be supplied to device 10 from a user or external devices and to allow output to be provided from device 10 to the user or external devices.

Input-output circuitry 32 may include wired and wireless communications circuitry 34. Communications circuitry 34 may include radio-frequency (RF) transceiver circuitry formed from one or more integrated circuits, power amplifier circuitry, low-noise input amplifiers, passive RF components, one or more antennas, and other circuitry for handling RF wireless signals. Wireless signals can also be sent using light (e.g., using infrared communications).

Input-output circuitry 32 may include input-output devices 36 such as button 16 of FIG. 1, joysticks, click wheels, scrolling wheels, a touch screen such as display 14 of FIG. 1, other touch sensors such as track pads or touch-sensor-based buttons, vibrators, audio components such as microphones and speakers, image capture devices such as a camera module having an image sensor and a corresponding lens system, keyboards, status-indicator lights, tone generators, key pads, and other equipment for gathering input from a user or other external source and/or generating output for a user.

Sensor circuitry such as sensors 38 of FIG. 2 may include an ambient light sensor for gathering information on ambient light levels, proximity sensor components (e.g., light-based proximity sensors and/or proximity sensors based on other structures), accelerometers, gyroscopes, magnetic sensors, and other sensor structures.

Device 10 may also include other components 41 such as one or more batteries, power regulator circuitry (e.g., a power management unit integrated circuit), components such as the components in circuitry 32 and 40, etc.

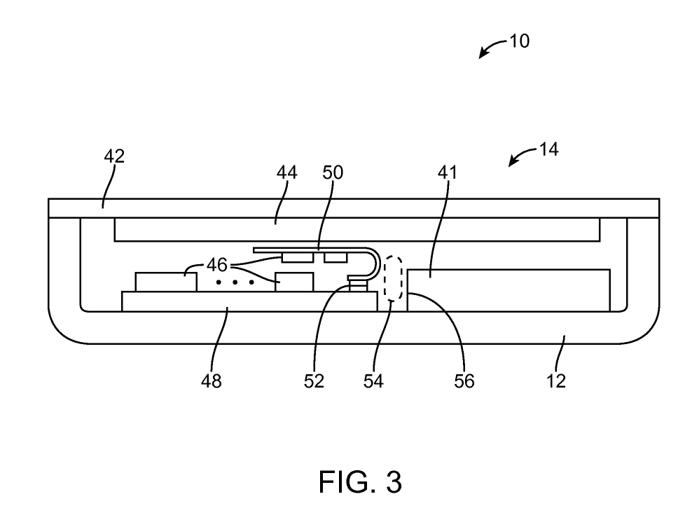

A cross-sectional side view of electronic device 10 is shown in FIG. 3. As shown in FIG. 3, display 14 may be mounted in housing 12. Display structures 44 such as a liquid crystal display module, an organic light-emitting diode display layer, or other display structures that include an array of active display pixels may be formed in an active area of display 14 under display cover layer 42. Display cover layer 42 may be formed from a clear glass layer, a layer of transparent plastic, or other cover layer material. A layer of ink (e.g., black ink or white ink or ink of other colors) or other opaque masking material can be formed on the underside of display cover layer 42 in an inactive display region surrounding the active area.

Device 10 may contain one or more substrates such as substrate 48 and substrate 50. Substrates such as substrates 48 and 50 may be mounted adjacent to internal components 41 (e.g., a battery, housing structure, integrated circuit, connector, support structure, sensor, input-output component, a component that forms part of circuitry 32 and/or 40, or other internal structures). Substrates such as substrates 48 and 50 may be coupled to each other using connectors such as connector 52. Components 46 may be mounted to substrates 48 and/or 50. Components 46 can include circuitry 40, input-output circuitry 32, integrated circuits, radio-frequency shielding cans, sensors, connectors, and other electronic devices.

Substrates 48 and 50 may be dielectric carriers such as molded plastic carriers or a pieces of glass or ceramic. With one suitable arrangement, which is sometimes described herein as an example, substrates such as substrates 48 and 50 are printed circuits. For example, substrates 48 and 50 may each be a printed circuit such as a rigid printed circuit board formed from a dielectric material such as fiberglass-filled epoxy or a flexible printed circuit formed from a dielectric layer such as a sheet of polyimide or other flexible polymer layer. Metal interconnect paths may be provided on substrates 48 and 50 to allow substrates such as substrates 48 and 50 to covey signals between components.

In general, there may be any suitable number of substrates within device 10 (e.g., one or more substrates, two or more substrates, three or more substrates, ten or more substrates, etc.). Connections between substrates may be formed from welds, solder balls, conductive adhesive connections such as connections formed form anisotropic conductive film, fasteners, zero-insertion-force connectors, or other electrical coupling structures. As an example, printed circuits in device 10 such as printed circuits 48 and 50 may be connected together using board-to-board connectors or other printed circuit connectors.

There is a potential for internal device structures such as internal component 41 to shift during impact events (e.g., when device 10 is dropped). To prevent damage to internal device structures such as component 41, to prevent damage to printed circuits such as printed circuits 48 and 50, and/or to prevent damage to connectors such as connectors 52, protection structures 54 may be interposed between component 41 and connector 52. As shown in FIG. 3, for example, protection structures 54 may prevent unintended contact between an edge or other portion of component 41 such as end surface 56 of component 41 and adjacent device structures such as connector 52 and substrates 48 and 50. This contact might otherwise cause damage to component 41, connector 52, and/or substrates 48 and 50. Because protection structures 54 may be used in protecting printed circuit connector 52, structures such as structures 54 are sometimes referred to as printed circuit connector protection structures or flexible printed circuit connector protection structures. Protection structures 54 may be mounted adjacent to components within device 10 such as printed circuit substrate 48 (as an example).

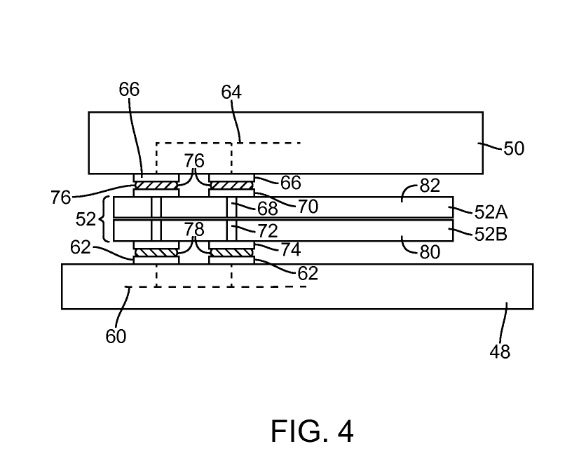

FIG. 4 is a cross-sectional end view of connector 52 in a configuration in which connector 52 is being used to interconnect a rigid substrate such as printed circuit board 48 to a flexible substrate such as flexible printed circuit 50. Printed circuit 48 has conductive interconnects such as metal traces 60 coupled to metal traces such as contact pads 62. Printed circuit 50 has conductive interconnects such as metal traces 64 coupled to metal traces such as contact pads 66. Using connector 52, traces 64 may be electrically connected to traces 60.

Connector 52 has first and second mating portions such as upper connector structure 52A and lower connector structure 52B. Upper connector structure 52A has contacts such as pins 68 that are supported by plastic connector body 82 and that are connected to respective contact pads such as contact pads 70. Upper connector 52A is mounted to flexible printed circuit substrate 50 using solder 76 that couples pads 70 and pads 66. Lower connector structure 52B has contacts such as pins 72 that are supported by plastic connector body 80 and that are connected to respective contact pads such as contact pads 74. Lower connector 52B is soldered to printed circuit substrate 48 using solder joints 78. Each solder joint 78 couples a respective one of printed circuit contact pads 62 to a respective one of connector solder pads 74. Other types of printed circuit connector may be used in coupling printed circuit substrates together in device 10. The configuration of FIG. 4 is merely illustrative.

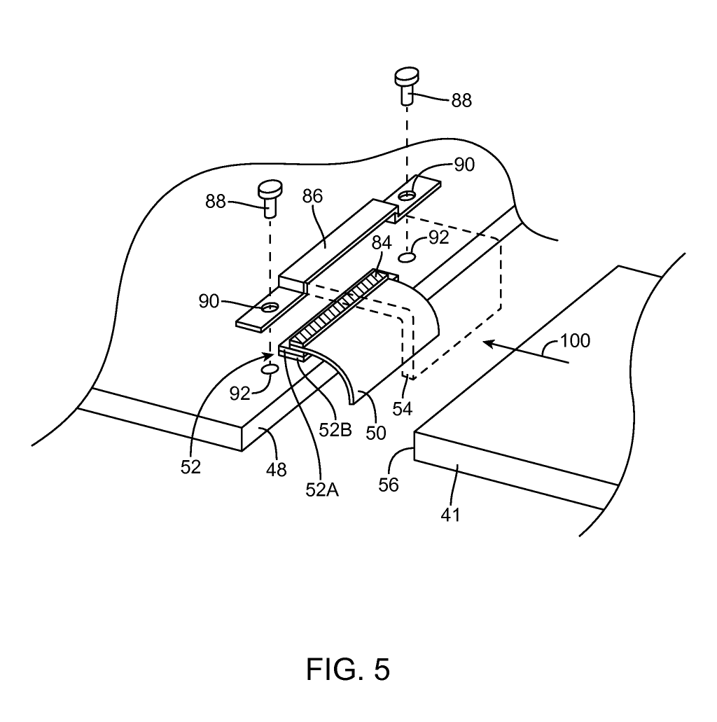

FIG. 5 is a partly exploded perspective view of an illustrative connector such as connector 52 of FIG. 4 being used to couple flexible printed circuit 50 to rigid printed circuit 48. In the illustrative configuration of FIG. 5, printed circuit connector structure 52A is mounted to flexible printed circuit 50 and mating printed circuit connector structure 52B is mounted to printed circuit 48. Stiffener 84 is formed from a rigid layer of metal or plastic (e.g., a thin sheet of stainless steel) to provide enhanced rigidity for flexible printed circuit 50 in the vicinity of connector 52. Stiffener 84 is attached to flexible printed circuit 50 using a layer of adhesive.

A bracket such as cowling 86 is mounted over connector 52 to help hold mating portions 52A and 52B of connector 52 together and to help retain connector 52 on printed circuit 48. Cowling 86 has openings 90 that are aligned with openings 92 in printed circuit 48. Screws 88 have threaded shafts that pass through openings 90 and 92. The threaded shafts of screws 88 may be received within threaded housing boss structures in housing 12 or may be provided with nuts or other threaded structures to attach cowling 86 to printed circuit 48.

There is a potential for damage if components such as component 41 move during an inadvertent drop event or other unexpected impact. Such an event might, for example, cause component 41 to move suddenly in direction 100, potentially allowing edge 56 of component 41 to strike structures in device 10 such as flexible printed circuit 50 or printed circuit 48. This could damage component 41, substrates 48 and/or 50, or other device structures and could dislodge connector 52A from connector 52B or may otherwise disconnect or damage connector 52. Device structures such as cowling 86 and stiffener 84 may also be vulnerable to dislodgement or damage.

To prevent damage, protection structures 54 may be interposed between component 41 and the other structures of FIG. 5 such as flexible printed circuit 50, substrate 48, connector 52, and cowling 86. Structures 54 may be formed from a bumper structure that clips onto the edge of printed circuit 48 or otherwise attaches to printed circuit 48, a structure of the type shown by the dashed lines of FIG. 5 in which metal or plastic structures have been attached to cowling 86, or other protection structures.

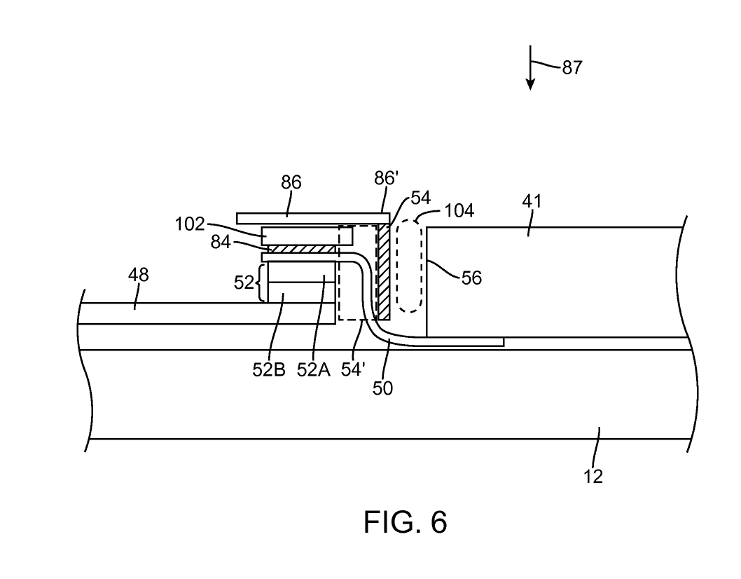

A cross-sectional side view of protection structures 54 in an illustrative configuration in which protection structures 54 have been formed from a material such as plastic that has been molded to a bracket structure such as cowling 86 is shown in FIG. 6. As shown in FIG. 6, cowling 86 may be used to hold together connector portions 52A and 52B in connector 52. Connector 52B is mounted to printed circuit 48. Connector 52A is mounted to flexible printed circuit 50. Stiffener 84 helps stiffen flexible printed circuit 50 in the vicinity of connector 52. Cowling 86 is screwed into board 48 using screws 88 (not shown in FIG. 6) or is otherwise mounted to board 48. Foam 102 is compressed between cowling 86 and stiffener 84 to help press connector 52 together.

Cowling 86 has a planar horizontal portion that runs parallel to the planar surface of printed circuit 48. Protection structures 54 in the FIG. 6 example are formed from a vertically extending plastic structure that has been molded onto horizontal protruding portion 86′ of cowling 86. With this configuration, vertical protection structures 54 lie perpendicular to the horizontal cowling 86. If desired, protection structures 54 can be provided with vertically extending sidewall portions 54′ on either edge of flexible printed circuit 50 (e.g., structures 54 may form a C-shaped structure that surrounds the outer edge and the sides of flexible printed circuit 50 when viewed in direction 87). Optional foam 104 may help prevent damage to component 41 in scenarios in which edge 56 of component 41 comes into contact with protection structures 54.

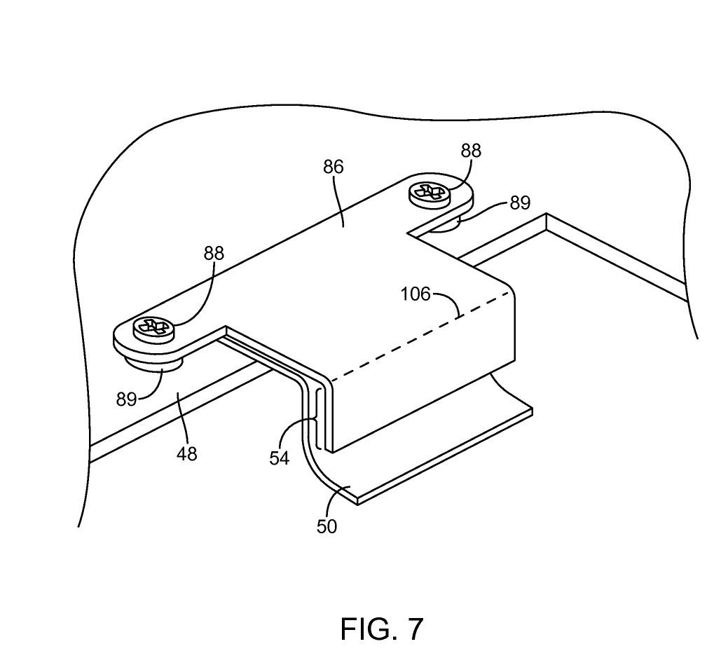

FIG. 7 is a perspective view of protection structures 54 that have been formed as an integral portion of cowling 86. Cowling 86 may be, for example, a sheet metal bracket with screw holes to accommodate screws 88. Screws 88 attach cowling 86 to printed circuit 48. Cowling 86 has a planar surface that lies parallel to the surface of printed circuit 48. The planar surface of cowling 86 runs horizontally parallel to printed circuit 48 and forms a tab-shaped protrusion. Bend 106 allows the horizontally protruding end of cowling 86 to extend vertically downwards. The vertical bent portion of cowling 86 forms protection structures 54 that lie in a plane that is perpendicular to the plane of the surface of printed circuit 48 and the plane of the upper surface of cowling 86. Standoffs 89 (e.g., plastic standoffs or metal standoffs) help establish a desired position for cowling 86 relative to the surface of printed circuit 48 (e.g., a height sufficient to clear connector 52).

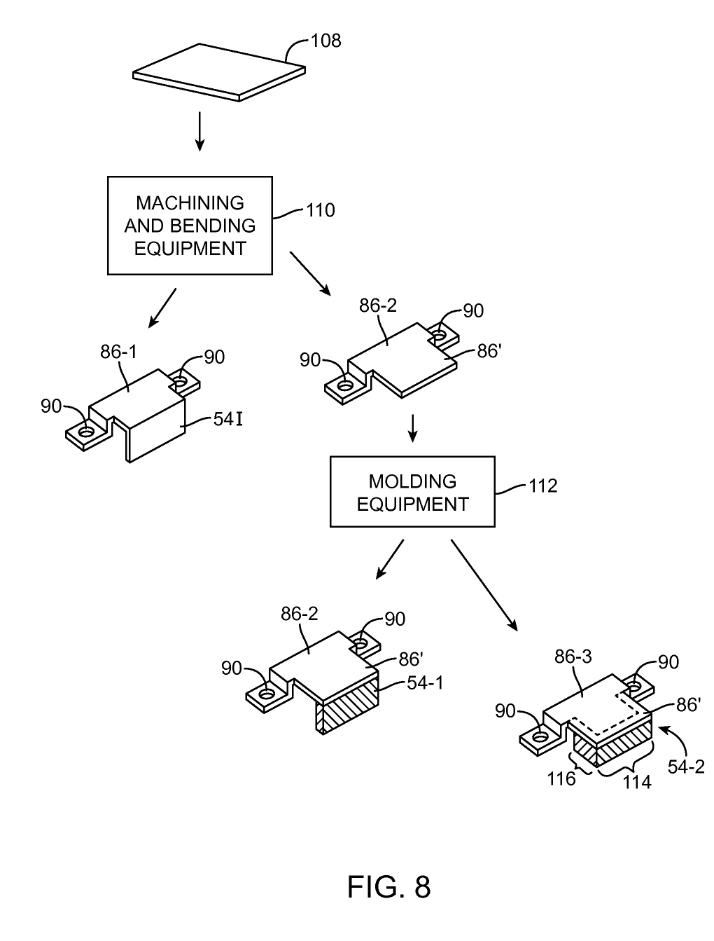

A diagram of systems and operations involved in forming protection structures 54 is shown in FIG. 8. As shown in FIG. 8, material 108 may be processed using manufacturing equipment 110. Material 108 may be, for example, sheet metal. Equipment 110 may include cutting equipment such as laser cutting equipment, machining equipment, water-jet cutting equipment and equipment for machining, bending, drilling, and otherwise shaping material 108 to form cowing 861 with an integral bent portion such as protection structures 541 and optional features such as screw holes 90.

If desired, equipment 110 may form a cowling structure such as cowling structure 86-2 that has a protruding tab portion such as tab 86′. Molding equipment such as plastic injection molding tool 112 can be used to injection mold a single-wall protection structure (i.e., protection structure 54-1) onto protruding portion 86′ of cowling 86-2 or can be used to form a three-wall protection structure, as illustrated by protection structure 54-2 on protruding portion 86′ of cowling 86-3. Three-wall protection structure 54-2 has a front vertical wall portion such as wall 114 that is interposed between component 41 and flexible printed circuit 50 and has sidewall portions such as sidewall 116. Sidewalls 116 lie on either side of flexible printed circuit 50 when the protection structures are installed on printed circuit 48 and rest against the leading edge of printed circuit 48 to help support from wall portion 114.

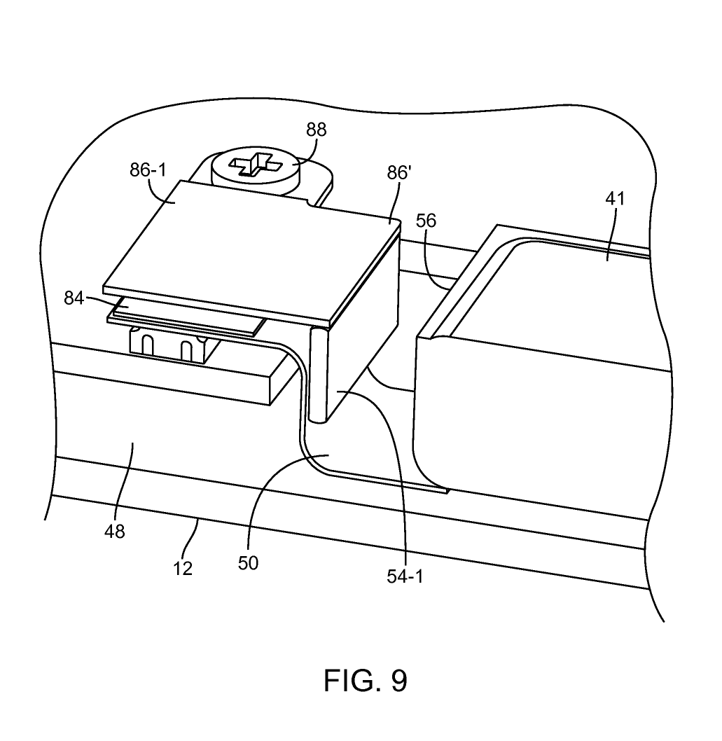

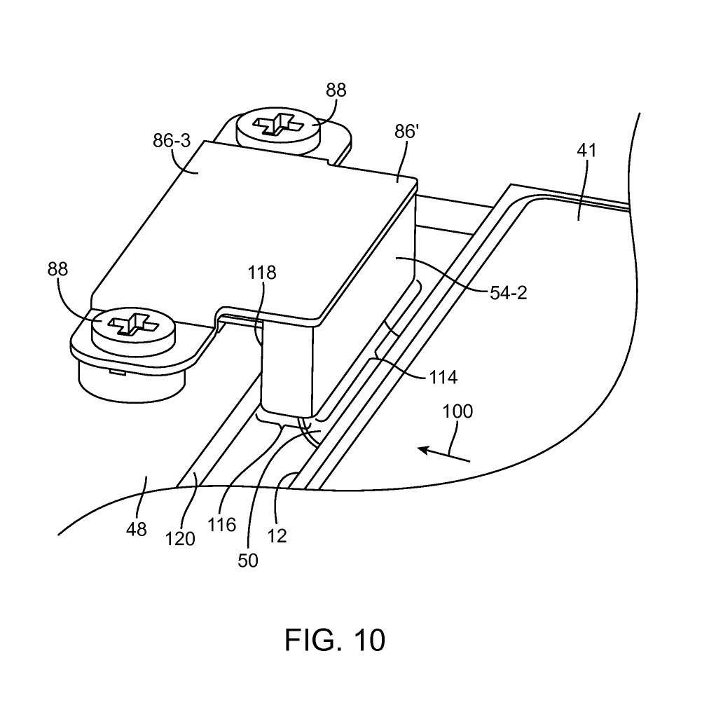

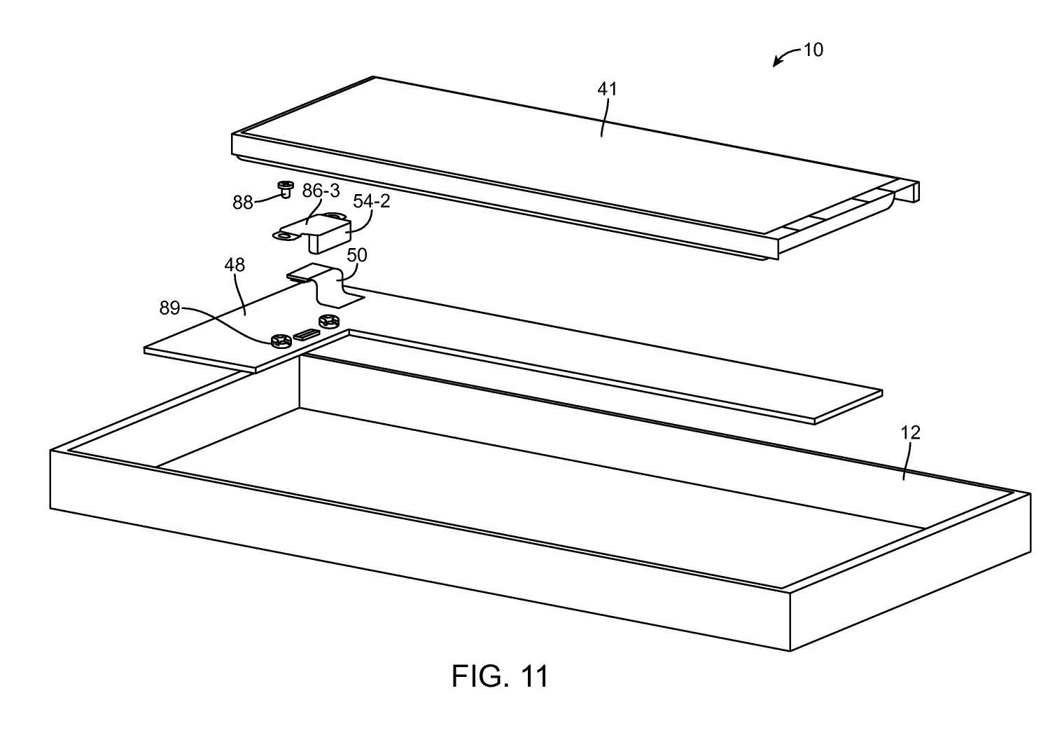

FIG. 9 is a cross-sectional perspective view of protection structures formed from cowling 86-2 and integral molded plastic protection structure wall 54-1 of FIG. 8. FIG. 10 is a perspective view of protection structures formed from cowling 86-3 and integral molded plastic protection structures 54-2 of FIG. 8. As shown in FIG. 10, trailing edge 118 of protection structure sidewalls 116 may rest against exposed edge 120 of printed circuit 48, thereby helping to support protection structure leading wall 114 in the event that component 41 slides into wall 114 in direction 100. An exploded perspective view of a portion of device 10 showing how component 41 may be a relatively large component that extends along the length of housing 12 is shown in FIG. 11.

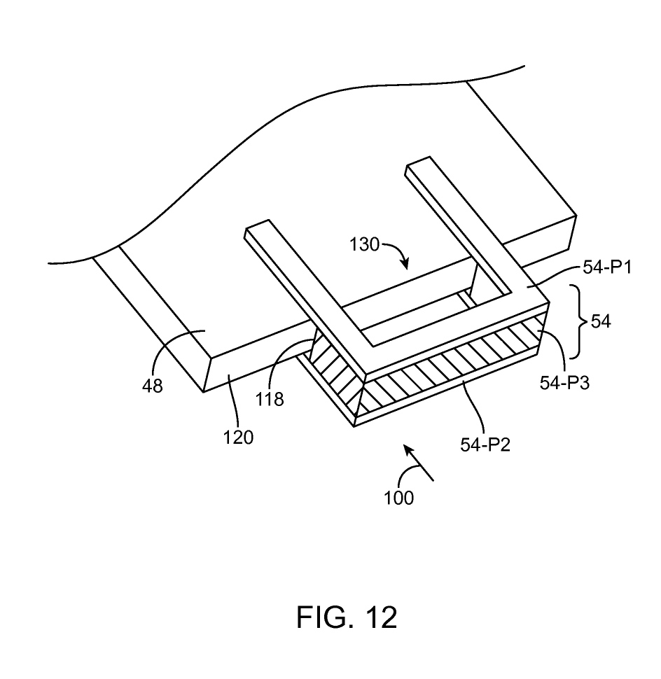

If desired, protection structures may be formed using a spring-based clip arrangement of the type shown in FIG. 12. Protection structures 54-P of FIG. 12 have upper U-shaped spring 54-P1 and lower U-shaped spring 54-P2 coupled by support structure 54-P3. Upper spring 54-P1 and lower spring 54-P2 grip the edge of printed circuit 48. Support structure 54-P3 holds upper spring 54-P1 and lower spring 54-P2 together to form protection structures 54. Support structures 54-P3 may be formed form plastic, metal, or other materials. Support structures 54-P3 and springs 54-P1 and 54-P2 may have U-shapes so that protection structures 54 form an opening such as opening 130 between protection structures 54 and edge 120 of printed circuit 48. Flexible printed circuit 50 and other structures in device 10 may be protected within opening 130. Edge 118 of support structure 54-P3 rests against edge 120 of printed circuit 48 to support protection structures 54 and prevent protection structures 54 from moving in direction 100 (e.g., when protection structures 54 are struck in direction 100 by a component such as component 41 of FIG. 11).

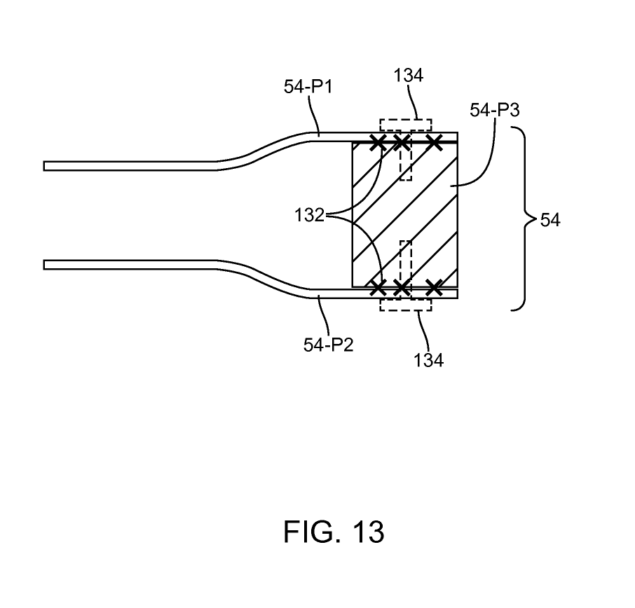

As shown in the cross-sectional side view of protection structures 54 of FIG. 13, upper spring 54-P1 and lower spring 54-P2 may be attached to support structure 54-P3 using coupling structures 132 such as adhesive, solder, or welds or may be attached to support structure 54-P3 using fasteners such as screws 134.

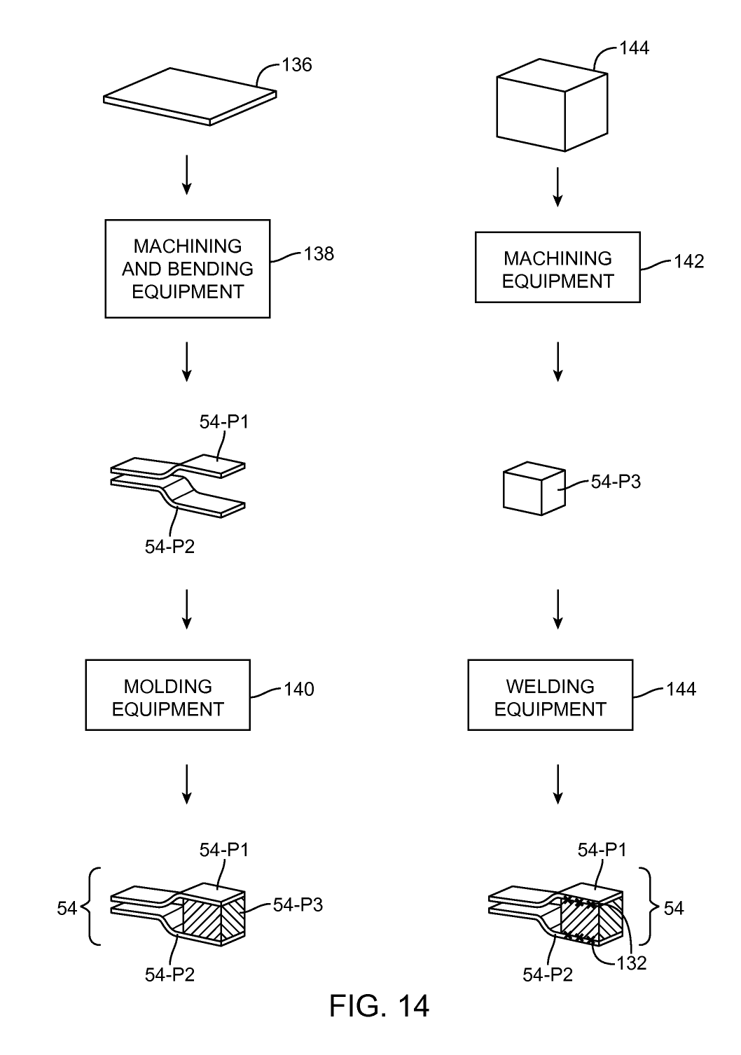

FIG. 14 is a diagram showing systems and operations involved in forming support structures 54 with springs such as upper spring 54-P1 and lower spring 54-P2. As shown in FIG. 14, springs 54-P1 and 54-P2 may be formed from material 136 using equipment such as machining and bending equipment 138 from material 136 (e.g., sheet metal or other spring material).

Support structure 54-P3 may be formed as an integral portion of protection structures 54 by using plastic injection molding equipment 140 to mold support structure 54-P3 onto springs 54-P1 and 54-P2. If desired, support structure 54-P3 may be formed from a first shot of plastic and springs 54-P1 and 54-P2 may be a second shot of plastic (e.g., a softer shot of plastic). Molding equipment 140 can form the first and second shots of plastic.

Alternatively, equipment such as machining equipment 142 can machine or otherwise process material 144 such as metal to form support structures 54-P3. Machined support structures 54-P3 produced by machining equipment 142 (or produced by molding equipment or other fabrication equipment) are attached to springs 54-P1 and 54-P2 by equipment 144 that forms bonds 132 (e.g., using welding equipment 144 that forms welds, equipment that applies adhesive or solder, etc.) or by using other coupling structures (e.g., fasteners such as screws, etc.).

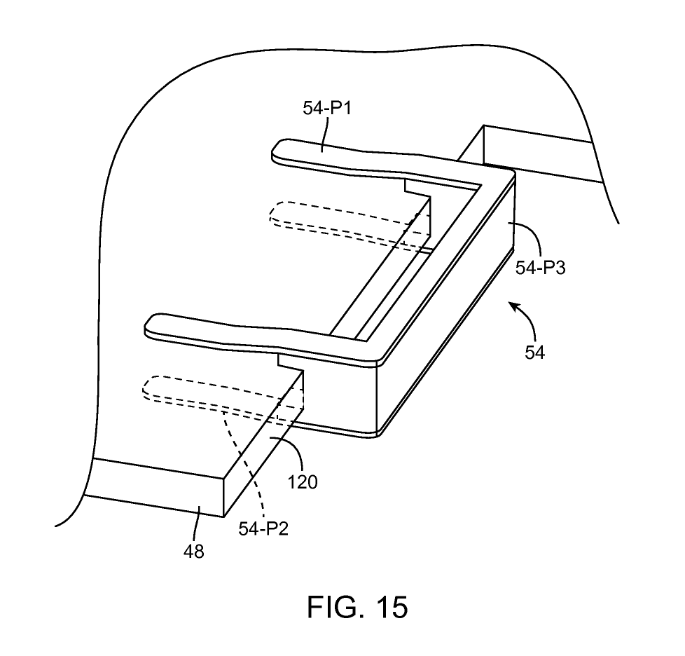

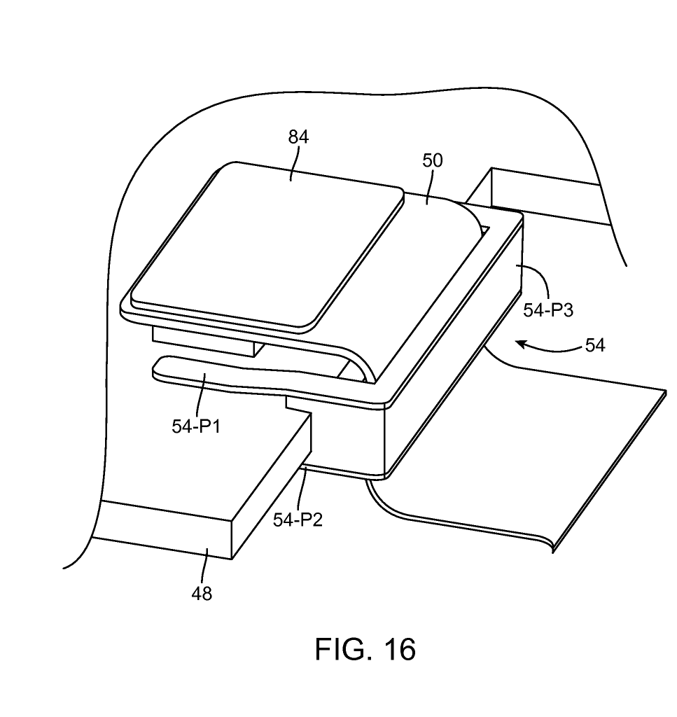

FIG. 15 is a perspective view of protection structures 54 having spring structures such as upper spring 54-P1 and lower spring 54-P2 coupled by support structures 54-P3. As shown in FIG. 15, spring-based protection structures 54 clip onto edge 120 of printed circuit 48. FIG. 16 shows how protection structures 54 such as the clip-type protection structures 54 of FIG. 15 can be used to protect board-to-board connector 52 and flexible printed circuit 50.

The foregoing is merely illustrative and various modifications can be made by those skilled in the art without departing from the scope and spirit of the described embodiments. The foregoing embodiments may be implemented individually or in any combination.

What is claimed is:

1. Apparatus, comprising:
a first printed circuit;
a second printed circuit;
a connector that couples traces in the second printed circuit to traces in the first printed circuit;
a bracket that holds the connector to the first printed circuit; and
a plastic protection structure molded to the bracket to protect the second printed circuit structure from damage.

2. The apparatus defined in claim 1 wherein the first printed circuit comprises a rigid printed circuit and wherein the second printed circuit comprises a flexible printed circuit, the apparatus further comprising:
an electronic device housing in which the rigid printed circuit is mounted; and
an internal component mounted in the housing adjacent to the plastic protection structure, wherein the plastic protection structure is interposed between an edge of the internal component and an edge of the rigid printed circuit.

3. The apparatus defined in claim 2 wherein the plastic protection structure comprises sidewalls having edges that contact the edge of the rigid printed circuit.

4. The apparatus defined in claim 3 wherein the plastic protection structure comprises a vertical wall that is interposed between the edge of the internal component and the edge of the rigid printed circuit.

5. The apparatus defined in claim 4 wherein the bracket comprises a metal cowling with screw holes that are used in holding the metal cowling over the connector.

6. The apparatus defined in claim 2 wherein the connector comprises a board-to-board printed circuit connector.

7. The apparatus defined in claim 2 wherein the internal component comprises a battery.

8. The apparatus defined in claim 1 where the bracket comprises a horizontal metal protrusion and wherein the plastic protection structure comprises injection molded plastic that forms at least one vertical wall portion extending vertically from the horizontal metal protrusion.

9. Apparatus, comprising:
a first printed circuit having a planar surface;
a second printed circuit;
a connector that couples traces in the first printed circuit to traces in the second printed circuit;
a bracket that holds the connector to the first printed circuit, wherein the bracket has a planar portion that extends parallel to the first printed circuit and a bent portion that extends perpendicular to the planar portion to protect the second printed circuit from damage.

10. The apparatus defined in claim 9 further comprising:
a battery mounted adjacent to the bent portion.

11. The apparatus defined in claim 10 further comprising an electronic device housing in which the battery and the first printed circuit are mounted, wherein the bracket has screw holes with which the bracket is mounted to the printed circuit.

12. The apparatus defined in claim 9 wherein the connector comprises a printed circuit board-to-board connector.

13. The apparatus defined in claim 12 wherein the first printed circuit comprises a rigid printed circuit and wherein the second printed circuit comprises a flexible printed circuit, the apparatus further comprising:
a metal stiffener on the flexible printed circuit; and
foam interposed between the bracket and the metal stiffener.

14. Apparatus, comprising:
a rigid printed circuit having an edge;
a flexible printed circuit;
a connector that couples traces in the flexible printed circuit to traces in the rigid printed circuit; and
a protection structure that clips onto the edge of the rigid printed circuit over the flexible printed circuit.

15. The apparatus defined in claim 14 wherein the protection structure comprises at least one metal spring structure.

16. The apparatus defined in claim 15 wherein the metal spring structure comprises a U-shaped metal spring.

17. The apparatus defined in claim 14 wherein the protection structure is configured to form an opening along the edge of the rigid printed circuit and wherein the flexible printed circuit passes through the opening.

18. The apparatus defined in claim 14 wherein the protection structure comprises:
upper and lower U-shaped springs that grip the printed circuit; and
a support structure that couples the upper and lower U-shaped springs.

19. The apparatus defined in claim 18 wherein the upper and lower U-shaped springs comprise metal and wherein the support structure comprises metal to which the upper and lower springs are welded.

20. The apparatus defined in claim 18 wherein the support structure is formed from a first shot of molded plastic and wherein the upper and lower U-shaped springs are formed from a second shot of molded plastic.
